(19) United States
(12) Patent Application Publication
(10) Pub. No.: US 2015/0361560 A1
(43) Pub. Date: Dec. 17, 2015

(54) RESIN ARTICLE HAVING PLATING LAYER AND METHOD OF MANUFACTURING THE SAME

(71) Applicant: CANON COMPONENTS, INC., Saitama-ken (JP)

(72) Inventor: Taisuke Iwashita, Saitama-ken (JP)

(21) Appl. No.: 14/740,864

(22) Filed: Jun. 16, 2015

(30) Foreign Application Priority Data
Jun. 17, 2014 (JP) 2014-124671

(51) Int. Cl. C23C 18/16; H05K 1/03; H05K 1/09; C23C 18/18

(52) U.S. Cl. CPC C23C 18/1641; C23C 18/1868; C23C 18/1682; H05K 1/0313; H05K 1/09

(57) ABSTRACT

There is provided with a method of manufacturing a resin article having a plating layer. A portion of a surface of a resin article is irradiated with ultraviolet rays. A binding agent is applied to the surface of the resin article. The binding agent binds the resin article with an electroless plating catalyst. The resin article applied with the binding agent is washed using an alkaline solution. The electroless plating catalyst is applied to the surface of the resin article after the resin article was washed. The resin article applied with the electroless plating catalyst is submerged in an electroless plating solution.

### BACKGROUND OF THE INVENTION

1. Field of the Invention

The present invention relates to a resin article having a plating layer and a method of manufacturing the same.

2. Description of the Related Art

A resin article on which a plating layer having a predetermined pattern is provided is useful as a circuit board, a conductive film, and the like. A method in which electroless plating is used has been known as a method of manufacturing such a resin article having a plating layer.

For example, Japanese Patent Laid-Open No. 2008-094923 discloses a method of manufacturing a circuit board using surface modification by means of ultraviolet rays. Specifically, first, the entire surface of a cycloolefin polymer substrate is irradiated with ultraviolet rays emitted from an ultraviolet lamp, and thus the surface of the substrate is modified. An electroless plating layer is likely to be deposited on the modified region. Thereafter, an alkaline degreasing treatment is performed on the substrate. It is conceivable that this treatment is performed so that the surface thereof is cleaned to improve the adherence with catalysts or the like. Moreover, a conditioning treatment is performed on the substrate, and a binding agent for binding a catalyst and the substrate is applied to the substrate in this treatment. After the binding agent absorbs the catalyst, the electroless plating is performed, as a result of which a plating layer is formed on the entire surface of the modified cycloolefin polymer substrate. Finally, photolithography and etching are performed so that the plating layer has a desired pattern.

Japanese Patent Laid-Open No. 2009-007613 discloses a method of forming the pattern of a plating thin layer on the surface of a polyimide resin substrate. Specifically, a resist pattern is formed on the surface of the polyimide resin substrate, and alkali modification, metal minute particle addition, and electroless plating are performed on a region exposed from an opening region of the resist pattern, as a result of which the plating thin layer is formed on the opening region of the resist pattern. The polyimide resin substrate has significantly excellent heat resistance compared with another resin substrate, and an example of such a polyimide resin substrate has a Tg of 200° C. or more. Also, the polyimide resin substrate has high mechanical strength and high versatility, and can be processed into a film, for example. Because of these reasons, almost all of flexible substrates are made of polyimide resin.

### SUMMARY OF THE INVENTION

According to an embodiment of the present invention, a method of manufacturing a resin article having a plating layer comprises: irradiating a portion of a surface of a resin article with ultraviolet rays; applying a binding agent to the surface of the resin article, the binding agent binds the resin article with an electroless plating catalyst; washing the resin article applied with the binding agent using an alkaline solution; applying the electroless plating catalyst to the surface of the resin article after the resin article was washed; and submerging the resin article applied with the electroless plating catalyst in an electroless plating solution.

According to another embodiment of the present invention, a resin article having a plating layer is manufactured by the method comprising: irradiating a portion of a surface of a resin article with ultraviolet rays; applying a binding agent to the surface of the resin article, the binding agent binds the resin article with an electroless plating catalyst; washing the resin article applied with the binding agent using an alkaline solution; applying the electroless plating catalyst to the surface of the resin article after the resin article was washed; and submerging the resin article applied with the electroless plating catalyst in an electroless plating solution.

Further features of the present invention will become apparent from the following description of exemplary embodiments with reference to the attached drawings.

### BRIEF DESCRIPTION OF THE DRAWINGS

FIGS. 1A and 1B are diagrams illustrating a method of manufacturing a resin article having a plating layer according to an embodiment.

FIG. 2 is a flowchart of a method of manufacturing a resin article having a plating layer according to an embodiment.

### DESCRIPTION OF THE EMBODIMENTS

In order to form a plating layer having a desired pattern using the method described in Japanese Patent Laid-Open No. 2008-094923 (Patent Document 1), photolithography and etching are required. It is also necessary that a resist pattern is formed through photolithography in the method described in Japanese Patent Laid-Open No. 2009-007613. Thus, there is a problem in that the methods described in Japanese Patent Laid-Open No. 2008-094923 and Japanese Patent Laid-Open No. 2009-007613 are costly and environmental load is high since a large amount of waste liquid is produced.

According to an embodiment of the present invention, a plating layer having a desired pattern can be formed on a resin article at low cost.

The inventor has known a technique for selectively modifying a portion of the surface of a resin article by applying the technique described in Patent Document 1 and selectively emitting ultraviolet rays in accordance with a desired pattern, instead of emitting ultraviolet rays toward the entire surface of a cycloolefin polymer substrate. According to this technique, a plating layer is selectively deposited on the portion irradiated with the ultraviolet rays through electroless plating. In other words, it is possible to obtain a plating layer having a desired pattern without performing a photolithography step and an etching step.

However, the inventor found an issue that there is a case where a pattern of the plating layer obtained using such a technique is not the same. The inventor found that a plating layer was sometimes deposited also on a portion that was not irradiated with ultraviolet rays, depending on conditions, such as the type of resin article to be used, for example. In the case where a polyimide resin substrate is used, for example, when selective plating was actually tried by selectively emitting ultraviolet rays, unnecessary plating was deposited also on portions other than the portion irradiated with ultraviolet rays, and thus a plating layer having a desired pattern could not be obtained.

The inventor considers that the reasons why the plating layer having a desired pattern could not be obtained are as follows. First, an example of a molecular structure of polyimide will be shown below.

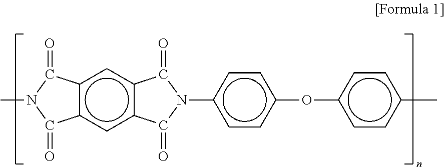

An alkali treatment performed on polyimide opens an imide ring, and generates a carboxyl group (—COOH), which is a chemically-absorptive group, as shown below.

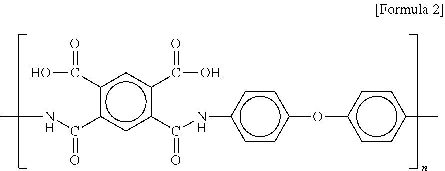

According to the method described in Patent Document 1, the alkaline degreasing treatment is performed and the conditioning treatment is performed using a binding solution, which is usually an alkaline solution. It is conceivable that opening of the imide ring of polyimide generates a chemically-absorptive group also on a portion that is not irradiated with ultraviolet rays at this time. Also, there is a carbonyl group (═O), which is a chemically-absorptive group, in the molecular structure of polyimide, and thus wettability is high. Therefore, it is conceivable that even if an imide ring is not opened, the binding agent is likely to be absorbed by polyimide.

Examples of chemically-absorptive groups include a hydroxyl group and the like. As described later, the chemically-absorptive group absorbs the binding agent, the binding agent absorbs a catalyst, and if a catalyst is present, a plating layer is deposited, and thus it is conceivable that the plating layer was deposited also on the portion that was not irradiated with ultraviolet rays.

As a result of studies, the inventor found that a step in which the resin article is washed using an alkaline solution is added after a binding agent for the resin article and an electroless plating catalyst is applied to the resin article modified by irradiation with ultraviolet rays. This step could reproducibly suppress deposition of the plating layer on the portion that was not irradiated with ultraviolet rays.

Even in the case where a resin that is modified by an alkaline solution or a resin having a high wettability is used, selective plating can be reproducibly performed using such a new method. In other words, the plating layer having a desired pattern could be formed on a resin article at low cost without performing a photolithography step and an etching step.

Hereinafter, an embodiment to which the present invention can be applied will be described with reference to drawings. However, the scope of the present invention is not limited to the following embodiment.

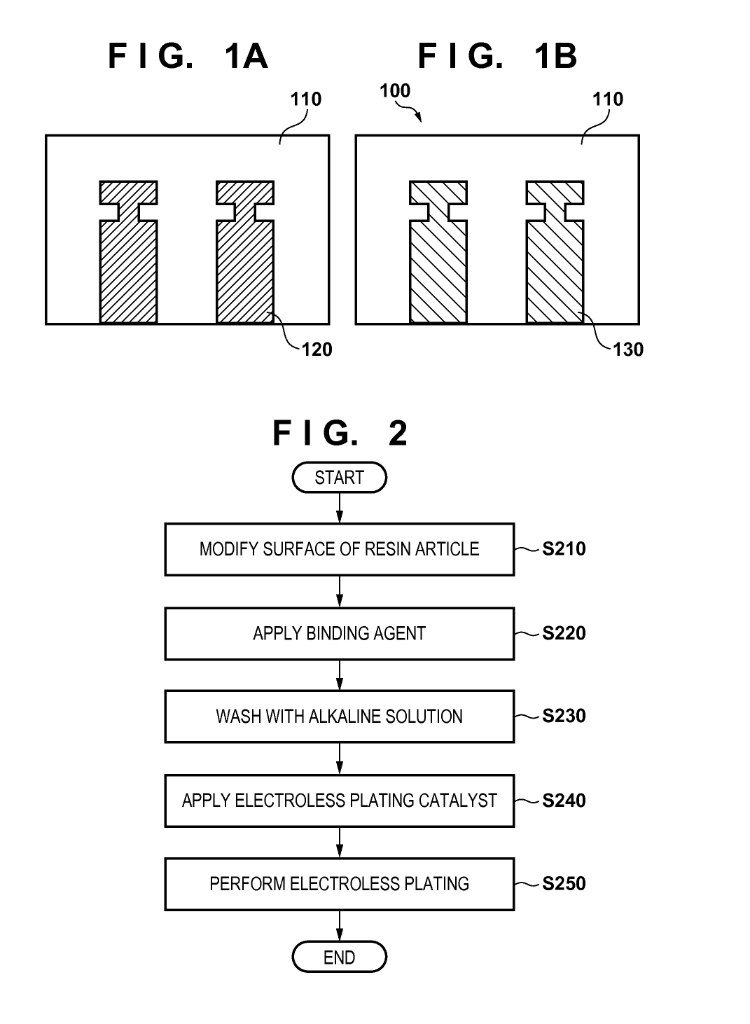

A method of manufacturing a resin article having a plating layer 100 according to an embodiment of the present invention includes a modifying step, a first applying step, a washing step, a second applying step, and a plating step. Hereinafter, these steps will be described with reference to FIGS. 1A, 1B, and 2.

Modifying Step

In the modifying step (step S210), a portion 120 of the surface of a resin article 110 is irradiated with ultraviolet rays. FIG. 1A illustrates the surface of the resin article 110 and the ultraviolet rays-irradiation portion 120. Irradiation with ultraviolet rays modifies the ultraviolet rays-irradiation portion 120.

In the embodiment, the resin article 110 is irradiated with ultraviolet rays in an atmosphere including oxygen or ozone. Specifically, the resin article 110 may be irradiated with ultraviolet rays in the air, for example. In another embodiment, in order to further promote modification, irradiation is performed in an atmosphere including ozone.

For example, if ultraviolet rays having a specific wavelength or less that can decompose oxygen are emitted in an atmosphere including oxygen, the oxygen in the atmosphere is decomposed into ozone. Furthermore, reactive oxygen is produced in the process in which ozone undergoes decomposition.

Energy of a photon having a specific wavelength will be expressed by the following equation.

E=Nhc/λ(KJ·mol⁻¹)
N=6.022×10²³ mol⁻¹ (Avogadro's number)
h=6.626×10⁻³⁷ KJ·s (Planck constant)
c=2.988×10⁸ m·s⁻¹ (Light velocity)
λ=wavelength of light (nm)

Here, binding energy of an oxygen molecule is 490.4 KJ·mol⁻¹. Conversion of the binding energy of oxygen molecule into wavelength of light using the equation of photon energy gives approximately 243 nm. This indicates that the oxygen molecule in the atmosphere absorbs ultraviolet rays having a wavelength of 243 nm or less and is decomposed. Accordingly, ozone O₃ is produced. Furthermore, reactive oxygen is produced in the process in which ozone undergoes decomposition. At this time, if there are ultraviolet rays having a wavelength of 310 nm or less, ozone is efficiently decomposed to produce reactive oxygen. Furthermore, ultraviolet rays having a wavelength of 254 nm most efficiently decomposes ozone.

O₂+hν(243 nm or less)→O(3P)+O(3P)

O₂+O(3P)→O₃ (ozone)

O₃+hν(310 nm or less)→O₂+O(1D) (reactive oxygen)

O(3P): oxygen atom in ground state

O(1D): excited oxygen atom (reactive oxygen)

Also, at the same time, bonds in molecules that constitute a resin are also cleaved at the surface of the resin due to ultraviolet rays having a short wavelength. At this time, molecules constituting the resin react with the reactive oxygen, and the surface of the resin is oxidized, that is, a C—O bond, a C═O bond, a C(═O)—O bond (skeletal portion of a carboxyl group), and the like are formed on the surface of the resin. Such a hydrophilic group has high affinity to a binding agent, which will be described later, and thus in the first applying step (step S220), the ultraviolet rays-irradiation portion 120 selectively absorbs the binding agent. Also, such a hydrophilic group increases chemical adsorptivity between the resin and plating. Furthermore, such a hydrophilic group forms a hydrogen bond with a water molecule or the like, improving the wettability of the resin article 110. Also, oxidation of the resin surface forms a surface having minute roughness in a nanolevel, and thus physical adsorptivity with the plating layer is increased due to an anchoring effect.

The rough surface caused by the oxidation at this time has a higher degree of flatness compared to those generated by a roughening method by means of a wet process in which chromic acid, permanganic acid, or the like is used, or a roughening method by means of a laser using a wavelength of 243 nm or more. According to this method, because of a higher degree of flatness, it is easy to deposit a plating layer having a minute pattern. Also, this method is suitable for the manufacture of a high-speed high-frequency substrate that needs a high degree of flatness.

There is no particular limitation on the method for irradiation with ultraviolet rays, and an ultraviolet lamp, an ultraviolet LED, or an ultraviolet laser can be used, for example. In an embodiment, ultraviolet rays are emitted from the ultraviolet lamp, or the like through a quartz/chromium mask, a metal mask, or the like on which a desired pattern is formed toward the resin article 110. Also, in another embodiment, the ultraviolet rays-irradiation portion 120 is scanned using ultraviolet rays emitted from the ultraviolet laser.

There is no particular limitation on the wavelength of ultraviolet rays, and ultraviolet rays that promote modification of the surface of the resin article 110 are selected. In an embodiment, the wavelength of the ultraviolet rays is 243 nm or less. The ultraviolet rays having a wavelength of 243 nm or less further promote modification of the surface of the resin article 110. The ultraviolet rays having a wavelength of 243 nm or less can decompose oxygen in the atmosphere, and generate ozone and reactive oxygen.

There is no particular limitation on the irradiation amount of ultraviolet rays, and the irradiation amount of ultraviolet rays can be appropriately selected so that plating is selectively deposited on the ultraviolet rays-irradiation portion 120. In general, it is conceivable that as the irradiation amount of ultraviolet rays increases, or in other words, as the ultraviolet intensity increases or the irradiation period gets longer, the modification of the portion 120 irradiated with the ultraviolet rays is facilitated, and plating is likely to be deposited.

In an embodiment, the cumulative irradiation amount of ultraviolet rays with regard to a dominant wavelength is 400 mJ/cm² or more, and in another embodiment, is 600 mJ/cm² or more. Also, in an embodiment, the cumulative irradiation amount thereof with regard to a dominant wavelength is 2000 mJ/cm² or less. In this specification, the irradiation amount and irradiation intensity of ultraviolet rays indicate the values at the dominant wavelength, unless otherwise stated. In this specification, the dominant wavelength refers to a wavelength having the highest intensity in a region of 243 nm or less. Specifically, in case of a low pressure mercury vapor lamp, the dominant wavelength is 185 nm.

Of course, a plating deposition condition can change in accordance with the type of plating solution, type of resin article 110, contamination degree of the surface of the resin article 110, concentration, temperature, pH, and chronological deterioration of the plating solution, change in output from the ultraviolet lamp or the like. In this case, it is sufficient that the irradiation amount of ultraviolet rays is appropriately determined with reference to the above-described numerical values.

There is no particular limitation on the resin article 110 as long as the resin article 110 has a surface having a resin material that can be modified so that plating is selectively deposited on an ultraviolet rays-irradiation portion. The manufacturing method according to the present embodiment can be used for the resin article 110 having a polyimide resin or a polyamide resin on the surface thereof. Among the resins, the polyimide resin has excellent heat resistance and strength, and thus soldering (including reflowing) can be performed on a circuit board obtained by forming a plating layer pattern on the polyimide resin substrate.

In the present embodiment, the resin article 110 made of a material that is modified by an alkaline solution can also be used. In an embodiment, a chemically-absorptive group is produced on the surface of the resin article 110 due to hydrolysis resulting from the alkali treatment. Examples of the chemically-absorptive groups include a hydroxyl group, a carbonyl group, and a carboxyl group. Also, in an embodiment, the surface of the resin article 110 includes at least one of an imide bond, an amide bond, and an ester bond.

Also, in the present embodiment, the resin article 110 made of a material having high wettability can also be used. In an embodiment, the surface of the resin article 110 includes a material having at least one of a hydroxyl group, a carbonyl group, and a carboxyl group. The resin having such a functional group has high wettability.

There is no particular limitation on the shape of the resin article 110, and the resin article 110 may be a substrate, or a film, for example. Also, the resin article 110 may be configured by a plurality of resin materials, have a layered structure of a plurality of resin materials, or be a composite material having a covered structure obtained by covering the surface of another material with a resin material.

Alkali Treatment

In an embodiment, in the modifying step (step S210), an alkali treatment is further performed on the resin article 110. The alkali treatment enables further modification of the surface of the resin article 110. In an embodiment, the resin article 110 has a resin material whose surface is modified by the alkali treatment, or in other words, the resin article 110 has a resin material in which bonds between atoms are cleaved by the alkali treatment at the surface. Examples of resin materials that are likely to be modified by the alkali treatment include a polyimide resin, a polyamide resin, a polycarbonate resin, an acryl resin, and a polyester resin.

According to experiments conducted by the inventor, it was confirmed that a plating layer was more likely to be deposited on a portion irradiated with ultraviolet rays by performing the alkali treatment, compared to the case where the alkali treatment is not performed. It is conceivable that one of the reasons is that by performing the alkali treatment on the surface of the resin article modified by ultraviolet rays, the wettability is further improved due to hydrolysis or the like. Also, it is conceivable that one of the reasons is that the surface is cleaned, or in other words, ash produced at the time of modification is removed therefrom.

For example, in the case where polyimide is used as the resin article 110, if the alkali treatment is performed on the resin article 110, an imide ring is opened, as a result of which a carboxyl group or a carboxyl ion may be generated on the surface of the resin article 110. The carboxyl group or the carboxyl ion has high affinity to the binding agent, which will be described later, and thus in the first applying step (step S220), the ultraviolet rays-irradiation portion 120 is more likely to absorb the binding agent. Thus, because of the alkali treatment, electroless plating is more likely to be deposited on the ultraviolet rays-irradiation portion 120. On the other hand, the portion that is not irradiated with ultraviolet rays is also likely to absorb the binding agent due to the alkali treatment.

The alkali treatment may be selectively performed on the ultraviolet rays-irradiation portion 120, and alternatively may be performed on the entirety of the resin article 110. In this case, an alkali treatment condition may be appropriately selected such that the electroless plating is deposited on the ultraviolet rays-irradiation portion 120, whereas the electroless plating is not deposited on the portion that is not irradiated with ultraviolet rays. It is conceivable that in general, as the concentration of the alkali treatment solution increases and a submersion time period gets longer, the surface of the resin article 110 is further modified, and the electroless plating is more likely to be deposited. However, in the case where a material that sensitively reacts with an alkaline solution, such as polyimide, is used as the material for the resin article 110, it is not easy to determine the alkali treatment condition without employing the washing step which will be described later.

In an embodiment, the alkali treatment is performed through submerging the resin article 110 in the alkali treatment solution. An aqueous solution of an alkali metal hydroxide, an alkaline earth metal hydroxide, or the like can be used as the alkali treatment solution. Specific examples of the alkali treatment solutions include an aqueous solution of sodium hydroxide and an aqueous solution of potassium hydroxide. After the alkali treatment, the resin article 110 may be washed using water or the like.

A time period during which the resin article 110 is submerged in the alkali treatment solution can be appropriately selected such that the electroless plating is selectively deposited on the ultraviolet rays-irradiation portion 120. In an embodiment, the submersion time period is 10 seconds or more, and in another embodiment, 1 minute or more. Also, in an embodiment, the submersion time period is 20 minutes or less, and in another embodiment, 5 minutes or less.

The concentration of the alkali treatment solution can also be appropriately selected such that the electroless plating is selectively deposited on the ultraviolet rays-irradiation portion 120. In an embodiment, the concentration of the alkali metal hydroxide included in the alkali treatment solution is 0.010 mol/L or more, and in another embodiment, 0.10 mol/L or more, and in a further embodiment, 0.30 mol/L. Also, in an embodiment, the concentration of the alkali metal hydroxide included in the alkali treatment solution is 50 mol/L or less, and in another embodiment, 10 mol/L. Moreover, in another embodiment, the pH of the alkali treatment solution is 12.0 or more, in another embodiment, 13.0 or more, and in a further embodiment, 13.5 or more.

There is no particular limitation on the order of the alkali treatment and ultraviolet irradiation, and the ultraviolet rays-irradiation portion 120 is sufficiently modified by two modification methods being combined so that plating is deposited. In an embodiment, the alkali treatment is performed after irradiation with ultraviolet rays. Irradiation with ultraviolet rays causes minute unevenness on the ultraviolet rays-irradiation portion 120. It is conceivable that the region having unevenness has a large surface area, and is likely to be modified by the alkali treatment. Therefore, the ultraviolet rays-irradiation portion 120 can be significantly modified by performing the alkali treatment after irradiation with ultraviolet rays, and it is possible to suppress modification of the portion that is not irradiated with ultraviolet rays. It is conceivable that plating can be selectively deposited on the ultraviolet rays-irradiation portion 120 with ease, by applying the alkali treatment after irradiation with ultraviolet rays in this manner.

First Applying Step

In the first applying step (step S220), a binding agent for the resin article 110 and the electroless plating catalyst is applied to the surface of the resin article 110. Examples of generally used electroless plating catalysts include a tin-palladium colloidal catalyst including tin and palladium. Usually, this catalyst is surrounded by anions such as chloride ion Cl⁻ in a solution, and thus has a negative charge. Also, an acidic palladium complex catalyst in which tin is not used similarly has a negative charge. Meanwhile, oxygen atoms present on the surface modified by irradiation with ultraviolet rays have high electronegativity and have strong force that attracts electrons in the molecule, and thus these atoms also have a negative charge. Since both the catalyst and the surface of the substrate also have a negative charge, they repel each other. In view of this, the binding agent for binding the catalyst and the substrate is used. This binding agent can be a cationic polymer having a positive charge that is used also in the conditioning treatment described in Patent Document 1, for example.

As described above, the ultraviolet rays-irradiation portion 120 is modified in the modifying step (step S210), and thus the binding agent is likely to adhere to the ultraviolet rays-irradiation portion 120. As a result of the binding agent absorbing the catalyst in the later step, an electroless plating layer is deposited on the region. Also, it is conceivable that since the ultraviolet rays-irradiation portion 120 has minute unevenness, the binding agent goes into the depth of the unevenness, and thus the binding agent is not easily removed from the ultraviolet rays-irradiation portion 120. Meanwhile, there is a possibility that the binding agent adheres also to the portion that is not irradiated with ultraviolet rays.

A binding agent that has been conventionally used for electroless plating can be used as the binding agent. Examples of the binding agents include a cationic polymer. Specifically, a conditioner solution included in an electroless plating solution set such as a Cu—Ni plating solution set “AISL” available from JCU Corporation, for example, is used to apply the binding agent. In an embodiment, the conditioner solution is adjusted to be an alkaline solution having a pH of 12 or more, and then used. Also, another example of the binding agent that increases adhesiveness to the electroless plating catalyst includes conditioner series “OPC-300 series” available from Okuno Chemical Industries Co., Ltd.

Washing Step

In the washing step (step S230), the resin article 110 provided with the binding agent is washed using the alkaline solution. Washing the resin article 110 using the alkaline solution can remove the binding agent which may be a cationic polymer adhering to the portion of the surface of the resin article 110 that is not irradiated with ultraviolet rays. On the other hand, the binding agent is considered to go into the depth of the unevenness in the ultraviolet rays-irradiation portion 120, and thus it cannot be easily removed therefrom. Thus, it is possible to remove the binding agent adhering to the portion that is not irradiated with ultraviolet rays while leaving the binding agent adhering to the ultraviolet rays-irradiation portion 120.

A washing condition can be appropriately selected such that the binding agent adhering to the portion that is not irradiated with ultraviolet rays is selectively removed, and the electroless plating is deposited on the ultraviolet rays-irradiation portion 120 whereas the electroless plating is not deposited on the portion that is not irradiated with ultraviolet rays. In general, a large amount of binding agents can be removed by increasing the concentration of the alkaline solution and elongating an alkali washing time period.

In an embodiment, the washing step (step S230) is performed by submerging the resin article 110 in the alkaline washing solution. An aqueous solution of an alkali metal hydroxide, an alkaline earth metal hydroxide, or the like can be used as the alkaline washing solution. Specific examples of the alkaline washing solutions include an aqueous solution of sodium hydroxide and an aqueous solution of potassium hydroxide. After alkaline washing, the resin article 110 may be further washed using water or the like.

A time period during which the resin article 110 is submerged in the alkaline washing solution can be appropriately selected such that the electroless plating is selectively deposited on the ultraviolet rays-irradiation portion 120. In an embodiment, the submersion time period is 10 seconds or more, and in another embodiment, 1 minute or more. Also, in an embodiment, the submersion time period is 10 minutes or less, and in another embodiment, 3 minutes or less.

The concentration of the alkaline washing solution can also be appropriately selected such that the electroless plating is selectively deposited on the ultraviolet rays-irradiation portion 120. In an embodiment, the concentration of the alkali metal hydroxide included in the alkaline washing solution is 0.010 mol/L or more, and in another embodiment, 0.10 mol/L or more. Also, in an embodiment, the concentration of the alkali metal hydroxide included in the alkaline washing solution is 5.0 mol/L or less, and in another embodiment, 3.0 mol/L or less. Moreover, in another embodiment, the pH of the alkaline washing solution is 12.0 or more, and in another embodiment, 13.0 or more. Moreover, in an embodiment, the pH of the alkaline washing solution is 14.5 or less, and in another embodiment, 14.0 or less.

Second Applying Step

In a second applying step (step S240), the electroless plating catalyst is applied to the surface of the resin article 110 after alkaline washing. The electroless plating catalyst can be applied thereto in accordance with a conventionally known method.

For example, the electroless plating catalyst can be applied by using two steps, which will be described below.
The resin article 110 is submerged in a solution containing catalytic ions. Examples of catalytic ions include a palladium complex such as a HCl-acidic palladium complex and a negatively charged Sn—Pd colloidal catalyst.
The catalytic ions are reduced by submerging the resin article in a solution containing a reducing agent. In this manner, the catalyst is deposited. Examples of the reducing agent include hydrogen gas, dimethylamine borane, and sodium borohydride.

The electroless plating catalyst selectively adheres to the binding agent. For example, since the HCl-acidic palladium complex has a negative charge, the HCl-acidic palladium complex is absorbed by the cationic polymer having a positive charge. Thus, the electroless plating catalyst is selectively deposited on the ultraviolet rays-irradiation portion 120 that is provided with the binding agent.

As a specific example, an activator solution included in an electroless plating solution set such as the Cu—Ni plating solution set “AISL” available from JCU Corporation can be used to perform the second applying step (step S240). Also, examples of another electroless plating catalyst include OPC-80 and OPC-90, which are catalyst imparting agents available from Okuno Chemical Industries Co., Ltd. Since the Sn—Pd colloidal catalyst has a large particle size, the catalyst can be more efficiently applied by using the HCl-acidic palladium complex that easily goes into the minute unevenness.

Plating Step

In a plating step (step S250), the resin article 110 provided with the electroless plating catalyst is submerged in the electroless plating solution. In this manner, as shown in FIG. 1B, a plating layer 130 is deposited on the ultraviolet rays-irradiation portion 120 that is provided with the electroless plating catalyst.

There is no particular limitation on a specific method for electroless plating. Examples of electroless plating that can be adopted include electroless plating in which a formalin-based electroless plating bath is used and electroless plating in which hypophosphorous acid that is deposited at a low rate is used as the reducing agent. Also, in order to form a thicker plating layer, the plating layer 130 may be formed using a high-speed electroless plating method. Specific examples of electroless plating further include electroless nickel plating, electroless copper plating, and electroless copper/nickel plating.

The electroless plating conforming to such a method can be performed using an electroless copper/nickel plating solution included in an electroless plating solution set such as the Cu—Ni plating solution set “AISL” available from JCU Corporation, for example. If the hypophosphorous acid is used as the reducing agent, copper/nickel plating containing nickel can be performed in order that the plating layer has an autocatalytic property.

Since the plating layer formed by electroless plating in this manner is often thin, the thickness of the plating layer may be increased by further performing electroplating. There is no limitation on the material for a metal layer provided by electroplating, and examples thereof include copper, nickel, a copper-nickel alloy, zinc oxide, zinc, silver, cadmium, iron, cobalt, chromium, a nickel-chromium alloy, tin, a tin-lead alloy, a tin-silver alloy, a tin-bismuth alloy, a tin-copper alloy, gold, platinum, rhodium, palladium, and a palladium-nickel alloy. Also, silver or the like may be deposited on the plating layer 130 through displacement plating.

According to the present embodiment, the plating layer 130 is deposited on the ultraviolet rays-irradiation portion 120. On the other hand, since the binding agent adhering to the portion that has not been irradiated with ultraviolet rays is removed therefrom, the electroless plating catalyst is not added to the portion that has not been irradiated with ultraviolet rays and the plating layer is not deposited. For example, the plating layer is not deposited on the portion adjacent to the ultraviolet rays-irradiation portion 120. Accordingly, according to the method of the present embodiment, the plating layer 130 can be selectively deposited on the ultraviolet rays-irradiation portion 120 with high reproducibility.

### EXAMPLE

### Example 1

A polyimide sheet (product name “Kapton EN” available from DU PONT-TORAY CO., LTD., thickness: 50 μm) was used as the resin article 110.

First, the portion 120 of the resin article 110 on which a plating layer is to be formed was irradiated with ultraviolet rays via a photomask in the air. The condition of irradiation with ultraviolet rays was as follows.

Low pressure mercury vapor lamp: UV-300 available from SAMCO INC. (dominant wavelength: 185 nm, 254 nm)

Irradiation distance: 3.5 cm

Luminous intensity at irradiation distance of 3.5 cm: 5.40 mW/cm² (254 nm)
1.35 mW/cm² (185 nm)

Irradiation time: 10 minutes

At that time, the cumulative exposure amount was 1.35 mW/cm²×600 sec=approximately 810 mJ/cm².

Next, the alkali treatment was performed on the resin article 110 irradiated with ultraviolet rays. Specifically, the resin article 110 was submerged for 2 minutes in an aqueous solution of sodium hydroxide that was adjusted using the alkali treatment solution used in the Cu—Ni plating solution set “AISL” available from JCU Corporation to have a concentration of 0.90 mol/L at 25° C. Thereafter, the resin article 110 was firstly washed lightly in pure water at 25° C. for several seconds, and then stirred and washed in pure water at 50° C. for 1 minute.

Next, a binding agent applying treatment was performed on the resin article 110 that was subjected to the alkali treatment. Specifically, the resin article 110 was submerged at 25° C. for 2 minutes using the conditioner solution used in the Cu—Ni plating solution set “AISL” available from JCU Corporation. At that time, the conditioner solution was diluted to one tenth of the concentration specified by the manufacturer and then used. Thereafter, the resin article 110 was firstly washed lightly in pure water at 25° C. for several seconds, and then stirred and washed in pure water at 50° C. for 5 minutes.

Next, alkaline washing was performed on the resin article 110 that was subjected to the binding agent applying treatment. Specifically, the resin article 110 was submerged in an aqueous solution of sodium hydroxide having a concentration of 0.90 mol/L at 25° C. for 2 minutes. Thereafter, the resin article 110 was firstly washed lightly in pure water at 25° C. for several seconds, and then stirred and washed in pure water at 50° C. for 1 minute.

Next, the catalytic ion applying treatment was performed on the resin article 110 that was subjected to alkaline washing. Specifically, the resin article 110 was submerged at 25° C. for 2 minutes using the activator solution used in the Cu—Ni plating solution set “AISL” available from JCU Corporation. Thereafter, the resin article 110 was firstly washed lightly in pure water at 25° C. for several seconds, and then stirred and washed in pure water at 50° C. for 1 minute.

Next, the reduction treatment was performed on the resin article 110 that was subjected to the catalytic ion applying treatment. Specifically, the resin article 110 was submerged at 25° C. for 2 minutes using the accelerator solution used in the Cu—Ni plating solution set “AISL” available from JCU Corporation. Thereafter, the resin article 110 was firstly washed lightly in pure water at 25° C. for several seconds, and then stirred and washed in pure water at 50° C. for 1 minute.

Next, the electroless copper/nickel plating was performed on the resin article 110 that was subjected to the reduction treatment. Specifically, the electroless Cu—Ni plating solution used in the Cu—Ni plating solution set “AISL” available from JCU Corporation was heated to 60° C. and the resin article 110 was submerged therein for 5 minutes. Thereafter, the resin article 110 was firstly washed lightly in pure water at 25° C. for several seconds, and then stirred and washed in pure water at 50° C. for 1 minute. In this manner, the resin article having a plating layer 100 was produced.

As a result of the treatments above, five resin articles having the plating layer 100 were produced. With respect to all of the five resin articles having the plating layer 100, the plating layer 130 was formed on the ultraviolet rays-irradiation portion 120, but the plating layer was not formed on the portion that was not irradiated with ultraviolet rays. It was found that according to the method of Example 1, the plating layer could be selectively formed in this manner with high reproducibility.

### Example 2

Similarly to Example 1, the resin article having the plating layer 100 was produced, except that in alkaline washing, the resin article 110 was submerged in an aqueous solution of sodium hydroxide having a concentration of 8.3 mol/L at 25° C. for 2 minutes. In Example 2 as well, the plating layer 130 was formed on the ultraviolet rays-irradiation portion 120, but the plating layer was not formed on the portion that was not irradiated with ultraviolet rays.

### Example 3

Similarly to Example 1, the resin article having the plating layer 100 was produced, except that in alkaline washing, the resin article 110 was submerged in an aqueous solution of sodium hydroxide having a concentration of 0.18 mol/L at 25° C. for 2 minutes. In Example 3 as well, the plating layer 130 was formed on the ultraviolet rays-irradiation portion 120. Also, the plating layer was slightly formed on the portion that was not irradiated with ultraviolet rays.

### Example 4

Similarly to Example 1, the resin article having the plating layer 100 was produced, except that in alkaline washing, the resin article 110 was submerged in an aqueous solution of sodium hydroxide having a concentration of 0.90 mol/L at 25° C. for 5 minutes. In Example 4 as well, among the portions 120 irradiated with ultraviolet rays, only very few portions on which the plating layer 130 was deposited insufficiently were observed. On the other hand, the plating layer was not formed on the portion that was not irradiated with ultraviolet rays.

### Example 5

Similarly to Example 1, the resin article having the plating layer 100 was produced, except that in the alkali treatment, the resin article 110 was submerged for 5 minutes in an aqueous solution of sodium hydroxide that was adjusted using the alkali treatment solution used in the Cu—Ni plating solution set “AISL” available from JCU Corporation to have a concentration of 0.90 mol/L at 25° C. In Example 5 as well, the plating layer 130 was formed on the ultraviolet rays-irradiation portion 120, but the plating layer was not formed on the portion that was not irradiated with ultraviolet rays.

### Example 6

Similarly to Example 1, the resin article having the plating layer 100 was produced, except that in the alkali treatment, the resin article 110 was submerged for 2 minutes in an aqueous solution of sodium hydroxide that was adjusted using the alkali treatment solution used in the Cu—Ni plating solution set “AISL” available from JCU Corporation to have a concentration of 0.18 mol/L at 25° C. In Example 6 as well, the plating layer 130 was formed on the ultraviolet rays-irradiation portion 120, but the plating layer was not formed on the portion that was not irradiated with ultraviolet rays.

### Comparative Example 1

Similarly to Example 1, the resin article having the plating layer 100 was produced, except that alkaline washing was not performed. In Comparative Example 1, the plating layer was formed on the portion that was not irradiated with ultraviolet rays.

### Comparative Example 2

Similarly to Example 1, the resin article having the plating layer 100 was produced, except that in the alkali treatment, the resin article 110 was submerged for 2 minutes in an aqueous solution of sodium hydroxide that was adjusted using the alkali treatment solution used in the Cu—Ni plating solution set “AISL” available from JCU Corporation to have a concentration of 8.3 mol/L at 25° C. In Comparative Example 2, the plating layer 130 was not formed also on the ultraviolet rays-irradiation portion 120. It is conceivable that this is because polyimide modified by ultraviolet rays dissolved due to an aqueous solution of sodium hydroxide.

According to the result above, it was found that performing alkaline washing after the binding agent applying treatment could suppress deposition of the plating layer on the portion that was not irradiated with ultraviolet rays.

Especially, as can be understood from Example 3, it was observed that the plating layer was likely to be deposited thereon in the case of performing weaker alkaline washing. It is conceivable that this is because that the efficiency of removing the binding agent adhering to the portion that is not irradiated with ultraviolet rays decreases. Also, as can be understood from Example 4, it was observed that the plating layer was unlikely to be deposited thereon in the case of performing stronger alkaline washing. It is conceivable that this is because that the binding agent adhering to the portion irradiated with ultraviolet rays is removed.

Meanwhile, as shown in the Examples 1 to 4, the strength of alkaline washing is easily adjusted by adjusting the submersion time period and the concentration of the alkaline solution. Also, since the plating layer could be selectively deposited on the portion irradiated with ultraviolet rays using various concentrations of the alkaline solution in the Examples 1 and 2, it is conceivable that a permissible range of the strength of alkaline washing is wide. Therefore, it is conceivable that it is easy for persons skilled in the art to adjust the strength of alkaline washing such that the plating layer 130 is deposited on the ultraviolet rays-irradiation portion 120 and the plating layer is not deposited on the portion that is not irradiated with ultraviolet rays, taking the type of resin article 110 into consideration.

Also, as can be understood from the Examples 1, 5, and 6, it is conceivable that a permissible range of the strength of the alkali treatment is also wide. Therefore, it is conceivable that it is easy for persons skilled in the art to adjust the strength of the alkali treatment such that the plating layer 130 is deposited on the ultraviolet rays-irradiation portion 120 and the plating layer is not deposited on the portion that is not irradiated with ultraviolet rays, taking the type of resin article 110 into consideration.

While the present invention has been described with reference to exemplary embodiments, it is to be understood that the invention is not limited to the disclosed exemplary embodiment. The scope of the following claims is to be accorded the broadest interpretation so as to encompass all such modifications and equivalent structures and functions.

This application claims the benefit of Japanese Patent Application No. 2014-124671, filed Jun. 17, 2014, which is hereby incorporated by reference herein in its entirety.

What is claimed is:

1. A method of manufacturing a resin article having a plating layer, comprising:
irradiating a portion of a surface of a resin article with ultraviolet rays;
applying a binding agent to the surface of the resin article, the binding agent binds the resin article with an electroless plating catalyst;
washing the resin article applied with the binding agent using an alkaline solution;
applying the electroless plating catalyst to the surface of the resin article after the resin article was washed; and
submerging the resin article applied with the electroless plating catalyst in an electroless plating solution.

2. The method according to claim 1, wherein a pH of the alkaline solution is 12.0 or more.

3. The method according to claim 1, wherein the alkaline solution is a solution of an alkali metal hydroxide.

4. The method according to claim 1, wherein in the washing, the resin article is submerged in the alkaline solution for not less than 10 seconds and not more than 10 minutes.

5. The method according to claim 1, wherein the modifying further comprises treating the resin article using an alkaline solution.

6. The method according to claim 5, wherein the treating the resin article using an alkaline solution is performed after the resin article is irradiated with ultraviolet rays.

7. The method according to claim 1, wherein the binding agent is a cationic polymer.

8. The method according to claim 1, wherein before the resin article is irradiated with ultraviolet rays, the surface of the resin article includes a material having at least one of a hydroxyl group, a carbonyl group, and a carboxyl group.

9. The method according to claim 1, wherein a chemically-absorptive group is produced on the surface of the resin article by an alkali treatment.

10. The method according to claim 1, wherein the surface of the resin article includes at least one of an imide bond, an amide bond, and an ester bond.

11. The method according to claim 1, wherein the surface of the resin article includes a polyimide resin or a polyamide resin.

12. The method according to claim 1, wherein in the plating, a plating layer is deposited on the portion irradiated with ultraviolet rays, and a plating layer is not deposited on a portion adjacent to the portion irradiated with ultraviolet rays.

13. The method according to claim 1, wherein in the modifying, ultraviolet rays having a wavelength of 243 nm or less are emitted.

14. The method according to claim 1, wherein the modifying is performed in an atmosphere including oxygen or ozone.

15. A resin article having a plating layer, manufactured by a method comprising:
irradiating a portion of a surface of a resin article with ultraviolet rays;
applying a binding agent to the surface of the resin article, the binding agent binds the resin article with an electroless plating catalyst;
washing the resin article applied with the binding agent using an alkaline solution;
applying the electroless plating catalyst to the surface of the resin article after the resin article was washed; and
submerging the resin article applied with the electroless plating catalyst in an electroless plating solution.
